(19) United States
(12) Patent Application Publication
(10) Pub. No.: US 2025/0212572 A1
(43) Pub. Date: Jun. 26, 2025

(54) Semiconductor structure including light emitting element and manufacturing method thereof

(71) Applicant: UNITED MICROELECTRONICS CORP., Hsin-Chu City (TW)

(72) Inventors: SHENYONG SHI, Singapore (SG); HAO SU, Singapore (SG)

(73) Assignee: UNITED MICROELECTRONICS CORP., Hsin-Chu City (TW)

(21) Appl. No.: 18/420,792

(22) Filed: Jan. 24, 2024

(30) Foreign Application Priority Data
Dec. 26, 2023 (CN) 202311811122.4

(51) Int. Cl. H01L 33/62; H01L 25/075

(52) U.S. Cl. CPC H10H 20/857; H01L 25/0753; H10H 20/0364

(57) ABSTRACT

The invention provides a semiconductor structure including light emitting elements, the semiconductor structure includes a substrate, a display region and a contact pad region are defined on the substrate, a circuit layer is formed on the substrate, and the circuit layer is located in the display region and the contact pad region, a plurality of contact plugs are located in the display region and the contact pad region and electrically connected with the circuit layer, the plurality of contact plugs in the display region are arranged in an array, and a plurality of light emitting elements are located in the display region and electrically connected with the contact plugs.

### BACKGROUND OF THE INVENTION

### 1. Field of the Invention

The invention relates to the field of semiconductor manufacturing, in particular to a semiconductor structure integrating a display region and a bonding pad region.

### 2. Description of the Prior Art

In the semiconductor manufacturing process, after electronic components and multi-layer circuit layers are formed on the substrate, a re-distribution layer or bonding pads are often formed on the top of the stacked circuit layers to connect these electronic components to other larger pins and to connect other electronic components or voltage sources.

With the progress of semiconductor manufacturing process, the size of various components is getting smaller and smaller, and more components need to be accommodated in the limited space. Therefore, the structure of integrating a variety of circuit areas with different functions on the same substrate has gradually developed.

### SUMMARY OF THE INVENTION

The invention provides a semiconductor structure containing light emitting elements, which comprises a substrate, wherein a display region and a bonding pad region are defined on the substrate, a circuit layer is formed on the substrate, and the circuit layer is located in the display region and the bonding pad region, a plurality of contact plugs are located in the display region and the bonding pad region and electrically connected with the circuit layer, wherein the plurality of contact plugs in the display region are arranged in an array, and a plurality of light emitting elements are located in the display region and electrically connected with the contact plugs.

The invention further provides a method for forming a semiconductor structure containing light emitting elements, which comprises the following steps: providing a substrate, defining a display region and a bonding pad region on the substrate, forming a circuit layer on the substrate, wherein the circuit layer is located in the display region and the bonding pad region, forming a plurality of contact plugs which are located in the display region and the bonding pad region and electrically connected with the circuit layer, wherein the plurality of contact plugs in the display region are arranged in an array, and forming a plurality of light emitting elements which are located in the display region and electrically connected with the contact plugs.

The invention is characterized in that in order to reduce the waste of element space, the display region and the bonding pad region are integrated on the same substrate structure. Contact plugs and bonding pads arranged in an array are formed in the dielectric layer near the top surface of the display region to correspond to the pixels (light emitting elements) formed in the display region. The invention can manufacture a high-precision pixel array, and the dielectric layer on the surface of the display region also has a flat surface, thereby improving the display effect of the display region and the yield of products.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a schematic diagram of an element region and a bonding pad region of a semiconductor structure according to an embodiment of the present invention.

FIG. 2 shows a schematic diagram of a cross-sectional structure near the top surface of the element region and the bonding pad region of the semiconductor structure according to an embodiment of the present invention.

FIG. 3 is a schematic top view of a display region and a bonding pad region of a semiconductor structure according to another embodiment of the present invention.

FIG. 4 is a schematic cross-sectional view of the display region and the top surface of the bonding pad region of the semiconductor structure according to another embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

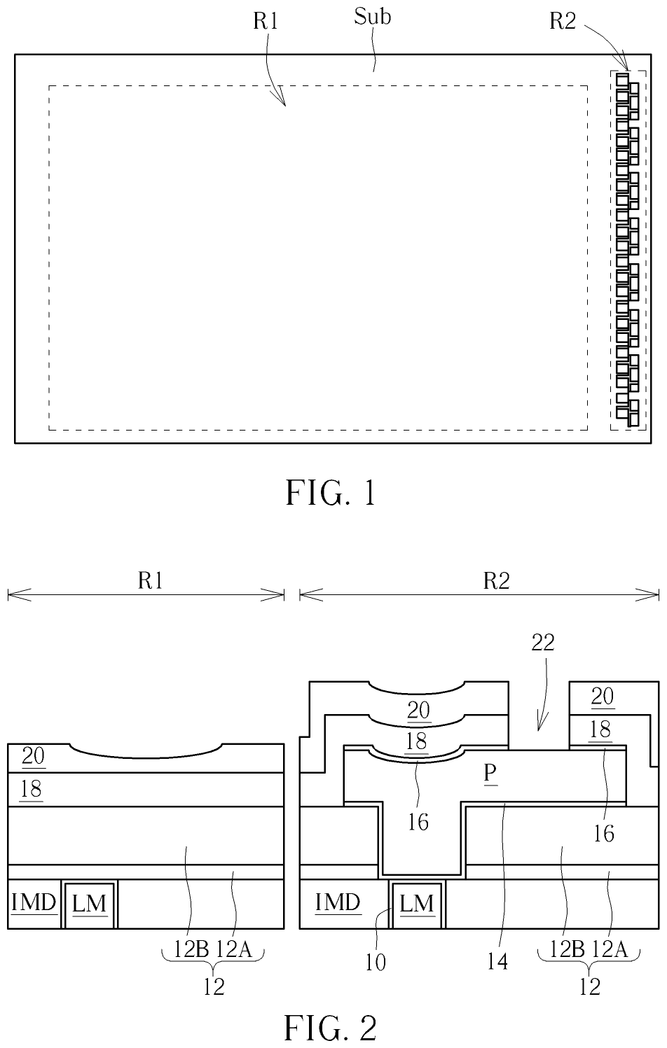

Please refer to FIG. 1 and FIG. 2. FIG. 1 shows a schematic diagram of an element region and a bonding pad region of a semiconductor structure according to an embodiment of the present invention, and FIG. 2 shows a schematic diagram of a cross-sectional structure near the top surface of the element region and the bonding pad region of the semiconductor structure according to an embodiment of the present invention. According to an embodiment of the present invention, firstly, a substrate Sub is provided, and an element region R1 and a bonding pad region R2 are defined on the substrate Sub, and a plurality of electronic elements and circuit layers are formed within the range of the element region R1 and the bonding pad region R2. The electronic elements described here, such as transistors, capacitors, inductors, resistors, memories, power amplifiers or other logic circuits, are located in a single-layer or multi-layer dielectric layer, but the present invention is not limited to this. Then a circuit layer is formed above the electronic component, and the function of the circuit layer is to electrically connect the electronic component to other layers above, and then to other electronic components or voltage sources through conductive pads. Usually, the circuit layer is a multi-layer stacked structure, which includes horizontally extending conductive layers (often called a metal layers) and vertical contact plugs (often called vias). Other technologies related to electronic components and circuit layers are known in this field, and will not be described here.

After the multi-layer circuit layers are formed, bonding pads are usually formed on the top of the circuit layer, and the function of the bonding pad is to provide a larger pin for connecting other electronic components. As shown in FIG. 1 and FIG. 2, in the element region R1 and the bonding pad region R2, the conductive layer LM represents the uppermost horizontal conductive layer in the multilayer circuit layers, and the conductive layer LM is located in an inter-metal dielectric layer IMD. The material of the inter-metal dielectric layer IMD is silicon oxide, for example, but not limited to this. The material of the conductive layer LM is, for example, a metal with good conductivity, such as tungsten, cobalt, copper, aluminum, gold, silver, etc., but it is not limited thereto. The outer side of the conductive layer LM may also include a liner 10, in which the material of the liner 10 is titanium/titanium nitride, for example, to improve the adhesion between the conductive layer LM and the inter-metal dielectric layer IMD, so that the conductive layer LM can be better formed in the inter-metal dielectric layer IMD.

Besides, others multilayer circuit layers and electronic components mentioned above are also included below the conductive layer LM, and these lower circuit layers and electronic components are not drawn here for the sake of simplicity. Next, in order to connect these electronic components with other electronic components outside the circuit layer, the circuit layer is concentrated in the bonding pad region R2, and then bonding pads P are formed in the bonding pad region R2. The bonding pads P are located in a dielectric layer 12, which may be a single layer or a multi-layer structure. In this embodiment, a multi-layer structure is taken as an example, which includes a stacked structure of a dielectric layer 12A and a dielectric layer 12B. The material of the dielectric layer 12A is silicon nitride, for example, and the material of the dielectric layer 12B is silicon oxide, but the invention is not limited to this. The material of the bonding pad P is made of metal, such as tungsten, cobalt, copper, aluminum, gold, silver, etc. In this embodiment, aluminum is taken as an example, but it is not limited to this. The outer side of the bonding pad P may also include a liner 14, and the material of the liner 14 may also be titanium/titanium nitride, but it is not limited to this.

Seen from the cross-sectional structure, the bonding pad P is located in a groove of the dielectric layer 12, and the bonding pad P is higher than the top surface of the groove and above the dielectric layer 12. In the process, a groove can be formed in the dielectric layer 12 to expose the underlying circuit layer LM, and then a liner 14 and a bonding pad material layer (such as an aluminum layer) are formed in the groove of the dielectric layer 12, wherein the liner 14 and the bonding pad P fill the groove and are located on the dielectric layer 12, and then a patterning step is used to remove part of the liner 14 and the bonding pad material layer located on the dielectric layer 12, and the remaining bonding pad material layer is the bonding pad P shown in FIG. 2. In addition, another liner 16, a dielectric layer 18 and a dielectric layer 20 may be included above the bonding pad P. The liner layer 16 may be made of titanium/titanium nitride, the dielectric layer 18 is made of phosphoglass (PSG), and the dielectric layer 20 is made of silicon nitride, but the above materials are not limited to this. In this embodiment, the thickness of the bonding pad P above the dielectric layer 12 is about 8000 angstroms, the thickness of the dielectric layer 18 is about 4000 angstroms, and the thickness of the dielectric layer 20 is about 5000 angstroms, but the present invention is not limited to this.

Next, an opening 22 is formed in the dielectric layer 20 and the dielectric layer 18, wherein the opening 22 exposes the bonding pad P, and the function of the opening 22 is to serve as a position for subsequently connecting the bonding pad P with other electronic components or voltage sources. That is to say, other electronic components or voltage sources can be connected to the bonding pad P through the opening 22, and further connected to the lower circuit layer and electronic components.

It is worth noting that in this embodiment, although circuit layers (LM) are formed in both the element region R1 and the bonding pad region R2, and a plurality of electronic components are formed in the element region R1, these electronic components and circuit layers are gathered in the bonding pad region R2 in the upper half of the multilayer structure, and are electrically connected with external electronic components through the bonding pad P in the bonding pad region R2. In other words, from the top view (FIG. 1), although circuit layers and electronic components (not shown) are both formed in the element region R1 and the bonding pad region R2, only the bonding pad region R2 contains exposed bonding pads P for connecting other external electronic components.

Therefore, in the embodiment shown in FIGS. 1 and 2, the surface of the element region R1 is covered by the dielectric layer 18 and the dielectric layer 20, and no other elements are formed in the element region R1, thus forming a blank region. With the development of semiconductor process, more and more devices are integrated on the same substrate, and manufacturers also hope to use the blank regions of devices, such as forming various devices in the blank regions to reduce the waste of device space. For example, in the wearable devices such as virtual reality (VR) glasses or augmented reality (AR) glasses used in the virtual reality and augmented reality technologies currently under development, the circuit layer and the display device may be fabricated on the same substrate. Under this development trend, the element region R1 in FIG. 1 can be considered to form light emitting elements to achieve the display effect.

However, if the structures shown in FIGS. 1 and 2 are directly applied to the surface of the element region R1 to form various light emitting elements, there will be several problems. Firstly, the surface of the element region R1 is not flat enough. The reason is that when forming elements such as bonding pads P in the bonding pad region R2, the element region R1 is a large-area empty region relative to the bonding pad region R2, so it is easy to generate dishing phenomenon on the surface of the dielectric layer 20 when performing planarization steps (such as chemical mechanical polishing), which leads to insufficient flatness of the surface dielectric layer 20 of the finally formed element region R1. If other elements (such as light emitting elements) are not formed on the surface of the element region R1, the surface depression of the element region R1 will not affect the electrical properties of the semiconductor structure. However, if it is necessary to form light emitting elements on the surface of the element region R1, the concave surface of the element region R1 becomes a problem to be solved.

Another problem is that because the function of the bonding pad P is to transfer the circuit layer with smaller size to the pins of other electronic components with larger size, the size of the bonding pad P needs to match the pin size of the electronic components and cannot be designed too small. In the current manufacturing process, the material layer (such as the aluminum layer) of the bonding pad P is directly filled into the groove of the dielectric layer 12, which leads to a relatively thick bonding pad P (about 8000 angstroms). If the circuit layer connecting the light emitting elements is formed in the element region R1 at the same time in the process of forming the bonding pad P, the thickness of the circuit layer in the element region R1 will be thicker. However, the thickness of the circuit layer is too large, which will lead to the increase of the aspect ratio of each element, so it is easy to cause the problem of insufficient material gap filling. If the gap and size of components are increased to solve the problem of material gap filling, it will face the problem of insufficient accuracy of circuit layer.

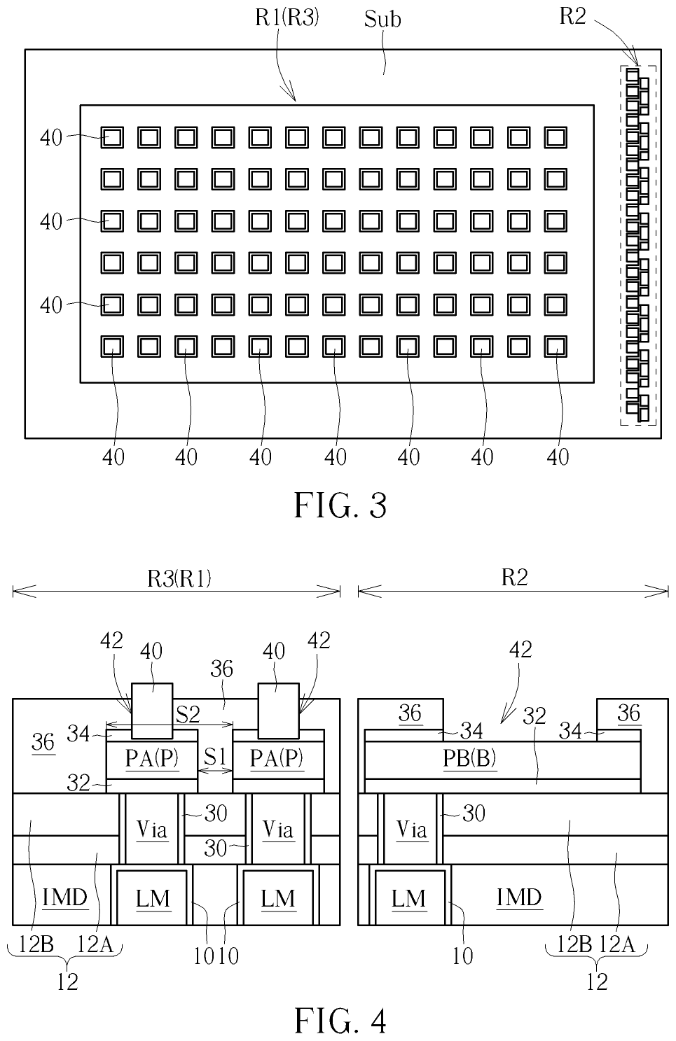

In order to solve the above problems and make a structure integrating light emitting elements and circuit layers, another embodiment of the present invention is proposed. FIG. 3 shows a top view schematic diagram of a display region and a bonding pad region of a semiconductor structure according to another embodiment of the present invention, and FIG. 4 shows a schematic diagram of a cross-sectional structure near the top surface of the display region and the bonding pad region of a semiconductor structure according to another embodiment of the present invention. As shown in FIG. 3 and FIG. 4, in this embodiment, an element region R1 and a bonding pad region R2 are also defined on the substrate Sub, wherein the element region R1 is a region formed by a plurality of electronic components, and these electronic components are integrated into the bonding pad region R2 through a circuit layer, and are connected to other external electronic components or a voltage source through a bonding pad P. Here, the definitions of the element region R1 and the bonding pad region R2 are the same as those of the above-mentioned first embodiment (the embodiment shown in FIGS. 1 and 2), and they are not repeated here.

It is worth noting that in this embodiment, a plurality of light emitting elements 40 are formed on the surface of the element region R1, and these light emitting elements 40 are arranged in an array, which can be combined into a plurality of pixel to achieve the effect of displaying pictures. Because the element region R1 of this embodiment has the function of displaying pictures, the element region R1 can be defined as a display region R3, which have the same range.

As mentioned above, in order to form light emitting elements with good quality in the display region R3, it is necessary to form a flat dielectric layer surface in the element region R1 (that is, the display region R3) and a circuit layer with high enough precision in the lower dielectric layer of the light emitting element in the display region R3. As shown in FIG. 4, in this embodiment, the display region R3 and the bonding pad region R2 also contain a conductive layer LM located in the inter-metal dielectric layer IMD, and a dielectric layer 12A and a dielectric layer 12B are stacked above the inter-metal dielectric layer IMD. These elements are the same as those described in the first embodiment, and will not be repeated here.

Next, contact plugs Via are formed on top of the IMD, wherein each contact plug Via is located in the display region R3 and the bonding pad region R2. A liner 30 may be included outside the contact plug Via. In this embodiment, the material of the contact plug Via is, for example, tungsten, and the material of the liner 30 is, for example, titanium/titanium nitride, but not limited thereto. The difference between this embodiment and the above embodiment is that the contact plugs Via are located in the dielectric layer 12A and the dielectric layer 12B, and the top surface of the contact plug Via is flush with the top surface of the dielectric layer 12B. The bonding pad P in the above embodiment is not only located in the groove of the dielectric layer 12A and the dielectric layer 12B, but also located on a part of the dielectric layer 12B. In this embodiment, after a metal layer such as tungsten is filled in the groove of the dielectric layer 12, the excess tungsten metal is ground off by chemical mechanical polishing and the like to form the contact plugs Via, so the contact plugs Via are manufactured separately from other circuit layers above. In this way, because the height of the contact plug Via is small, the size of the contact plug Via can also be made smaller, in other words, the contact plug Via with higher accuracy can be made.

It is worth noting that the contact plug Via in this embodiment is connected to the conductive layer LM located in the bonding pad region R2 as a structure for electrically connecting the subsequent bonding pads. While the contact plugs Via in the display region R3 are arranged in an array as a structure for subsequently electrically connecting the light emitting elements. Therefore, compared with the above-mentioned embodiment, this embodiment includes the contact plugs Via in the dielectric layers 12A and 12B in the display region R3 (or the element region R1), while the dielectric layers 12A and 12B in the element region R1 in the above-mentioned first embodiment do not include other conductive structures (such as the contact plugs).

Next, a plurality of conductive material layers are formed above the dielectric layer 12B, and then the redundant material layers are removed by a patterning step. As shown in FIG. 4, the remaining material layers are located on the dielectric layer 12B and include a liner 32, a bonding pad P and a top liner 34 in the display region R3 and the bonding pad region R2, and these material layers are electrically connected to the contact plug Via below. The function of the liner 32 and the top liner 34 here is to improve the connection quality between the bonding pad P and the contact plug Via and reduce the resistance of the interface. However, in other embodiments, the liner layer 32 and the top liner layer 34 can also be selectively omitted. In this embodiment, the liner 32 and the top liner 34 contain titanium/titanium nitride, and the material of the bonding pad P contains aluminum, but the present invention is not limited to this. Therefore, in this embodiment, the contact plug Via and the bonding pad P preferably comprise different materials, for example, the material of the bonding pad P comprises aluminum and the material of the contact plug Via comprises tungsten, but the present invention is not limited to this.

In addition, for the sake of clarity, the bonding pad in the display region R3 is defined as the bonding pad PA, and the bonding pad P in the bonding pad region R2 is defined as the bonding pad PB, but they are made of the same material and should be formed by the same step. Hereinafter, the reference to the bonding pad P refers to the bonding pad PA or the bonding pad PB. In this embodiment, the thickness of the bonding pad P is smaller than that of the bonding pad P in FIG. 2, and the thickness of the bonding pad P in this embodiment is about 1500 angstroms, but it is not limited to this. In this way, because the thickness of the bonding pad P is relatively thin, the aspect ratio of the gap between adjacent bonding pads PA will not be too high, which can solve the problem that the material layer cannot be completely filled. Taking this embodiment as an example, the gap spacing S1 between adjacent bonding pads PA is about 0.4 micron, and the thickness of bonding pads PA is about 1500 angstroms as mentioned above. Under this aspect ratio, the material layer formed subsequently can fill the gap between bonding pads PA. In addition, in this embodiment, the bonding pads PA are arranged in an array, for example, where the distance from one side of one bonding pad PA to the same side of another adjacent bonding pad PA is defined as S2, preferably, S2 is about 1.2 to 2.4 microns, but not limited to this.

Subsequently, a passivation layer 36 is formed to cover the dielectric layer 12B and the bonding pad P. The material of the passivation layer 36 is, for example, silicon oxide, silicon nitride, silicon oxynitride or phosphosilicate glass. Then, a plurality of light emitting elements 40 are formed in the display region R3 and electrically connected to the bonding pads PA in the display region R3. The light emitting elements 40, such as light-emitting diodes, have different colors (such as red, blue and green) to form different pixels. The light emitting elements 40 are arranged in the display region R3 to achieve the display function. In the actual manufacturing process, after the passivation layer 36 is completed, a plurality of openings 42 can be formed on the top surface of the passivation layer 36 by etching, etc., so as to expose the underlying bonding pads PB, and then the light emitting elements 40 can be formed in the openings in the display region R3 by mass transfer, etc., and are electrically connected and corresponding to the bonding pads PA in the display region R3. As for the opening 42 in the bonding pad region R2, the lower bonding pad P is also exposed for subsequent connection with other electronic components or voltage sources.

It is worth noting that after the passivation layer 36 is formed, an additional planarization step can be performed to flatten the surface of the passivation layer 36. Different from the above-mentioned first embodiment, in this embodiment, because a plurality of bonding pads PA are arranged below the passivation layer 36, the bonding pads PA may be arranged in an array corresponding to the positions of the light emitting elements 40. In the planarization step, the bonding pads PA arranged in an array under the passivation layer 36 can achieve the supporting effect, so as to avoid the dishing phenomenon caused by the large area of the passivation layer 36 in the display region R3. In other words, the bonding pads PA arranged in an array in this embodiment not only have the function of connecting the light emitting elements 40, but also can make the top surface of the passivation layer 36 flatter, so as to improve the display quality of the display region R3.

In this embodiment, the bonding pad PB in the bonding pad region R2 and the contact plug Via below can also be used as the bonding pad P, which means that other electronic components or voltage sources can be connected to the bonding pad PB later and the contact plug Via. Different from the first embodiment, in this embodiment, the bonding pad PB in the bonding pad region R2 and the contact plug Via below are made separately and preferably contain different materials, while the bonding pad P in the first embodiment (FIG. 2) is of an integrated structure.

Based on the above description and drawings, the present invention provides a semiconductor structure including light emitting elements, which includes a substrate Sub, a circuit layer LM formed on the substrate Sub and located in the display region R3 and the bonding pad region R2, a plurality of contact plugs Via located in the display region R3 and the bonding pad region R2 and electrically connected to the circuit layer LM, wherein the plurality of contact plugs Via in the display region R3 are arranged in an array, and a plurality of light emitting elements 40 located in the display region R3 and electrically connected with the contact plugs Via.

In some embodiments of the present invention, a plurality of first bonding pads PA are further included, which are located in the display region R3 and between the light emitting element 40 and the contact plug Via.

In some embodiments of the present invention, the first bonding pad PA directly contacts the contact plug Via and the light emitting element 40.

In some embodiments of the present invention, the plurality of light emitting elements 40 are not located in the bonding pad region R2.

In some embodiments of the present invention, a second bonding pad PB is further included, which is located in the bonding pad region R2, and the second bonding pad PB is electrically connected to the contact plug Via.

In some embodiments of the present invention, the top surface of the second bonding pad PB is connected to a signal source (i.e., a voltage source or other electronic components).

In some embodiments of the present invention, a passivation layer 36 is further included to cover the first bonding pad PA and the second bonding pad PB, and the passivation layer 36 includes a plurality of openings 42, each opening 42 exposes a part of the first bonding pad PA or the second bonding pad PB, and the light emitting element 40 is located in each opening 42 in the display region R1.

In some embodiments of the present invention, the first bonding pad PA and the second bonding pad PB are located in the passivation layer 36, and the thickness of the first bonding pad PA and the thickness of the second bonding pad PB are the same.

In some embodiments of the present invention, in the display region R3, each first bonding pad PA corresponds to each contact plug Via, and each first bonding pad PA presents an array arrangement.

In some embodiments of the present invention, in the display region, the spacing S1 between any two adjacent first bonding pads PA is between 0.3 micron and 0.5 micron.

In some embodiments of the present invention, the first bonding pad comprises a bottom layer (the liner 32), an intermediate layer and a top layer (the top liner 34), wherein the materials of the bottom layer and the top layer comprise titanium and titanium nitride, and the material of the intermediate layer comprises aluminum.

In some embodiments of the present invention, the ratio of an area of the display region R3 to an area of the bonding pad region R2 is greater than 20.

The invention further provides a method for forming a semiconductor structure containing light emitting elements, which comprises providing a substrate Sub, defining a display region R3 and a bonding pad region R2 on the substrate Sub, forming a circuit layer LM on the substrate Sub, wherein the circuit layer LM is located in the display region R3 and the bonding pad region R2, forming a plurality of contact plugs Via, which are located in the display region R3 and the bonding pad region R2 and are electrically connected with the circuit layer LM, wherein a plurality of contact plugs Via in the display region R3 are arranged in an array, and forming a plurality of light emitting elements 40, the plurality of light emitting elements 40 are located in the display region R3 and electrically connected with the contact plugs Via.

In some embodiments of the present invention, a plurality of first bonding pads PA are formed in the display region R3, and are located between the light emitting element 40 and the contact plug Via.

In some embodiments of the present invention, in the display region R3, each first bonding pad PA corresponds to each contact plug Via, and each first bonding pad PA presents an array arrangement.

In some embodiments of the present invention, the first bonding pad PA directly contacts the contact plug Via and the light emitting element 40.

In some embodiments of the present invention, it further includes forming a second bonding pad PB in the bonding pad region R2, and the second bonding pad PB is electrically connected to the contact plug Via.

In some embodiments of the present invention, a bonding pad P is formed, and a patterning step is performed on the bonding pad P to remove part of the bonding pad P. The remaining bonding pad P in the display region R3 is defined as the first bonding pad PA, and the remaining bonding pad P in the bonding pad region R2 is defined as the second bonding pad PB.

In some embodiments of the present invention, a passivation layer 36 is formed to cover the first bonding pad PA and the second bonding pad PB.

In some embodiments of the present invention, the passivation layer 36 is further planarized to make a top surface of the passivation layer 36 become a flat surface.

To sum up, the invention is characterized in that in order to reduce the waste of element space, the display region and the bonding pad region are integrated on the same substrate structure. Contact plugs and bonding pads arranged in an array are formed in the dielectric layer near the top surface of the display region to correspond to the pixels (light emitting elements) formed in the display region. The invention can manufacture a high-precision pixel array, and the dielectric layer on the surface of the display region also has a flat surface, thereby improving the display effect of the display region and the yield of products.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure comprising a light emitting element, comprising:
a substrate, on which a display region and a bonding pad region are defined;
a circuit layer formed on the substrate and located in the display region and the bonding pad region;
a plurality of contact plugs located in the display region and the bonding pad region and electrically connected with the circuit layer, wherein the plurality of contact plugs in the display region are arranged in an array; and
a plurality of light emitting elements located in the display region and electrically connected with the contact plugs.

2. The semiconductor structure according to claim 1, further comprising a plurality of first bonding pads located in the display region, and the plurality of first bonding pads located between the light emitting elements and the contact plugs.

3. The semiconductor structure according to claim 2, wherein each first bonding pad directly contacts the contact plug and the light emitting element.

4. The semiconductor structure according to claim 1, wherein the plurality of light emitting elements are not located in the bonding pad region.

5. The semiconductor structure according to claim 2, further comprising a second bonding pad located in the bonding pad region and electrically connected to the contact plug.

6. The semiconductor structure according to claim 5, wherein the top surface of the second bonding pad is connected with a signal source.

7. The semiconductor structure as claimed in claim 5, further comprising a passivation layer covering the first bonding pad and the second bonding pad, wherein the passivation layer comprises a plurality of openings, each opening exposes part of the first bonding pad or the second bonding pad, and the light emitting element is located in each opening in the display region.

8. The semiconductor structure according to claim 7, wherein the first bonding pad and the second bonding pad are located in the passivation layer, and a thickness of the first bonding pad and a thickness of the second bonding pad are the same.

9. The semiconductor structure according to claim 2, wherein in the display region, each of the first bonding pads corresponds to each of the contact plugs, and each of the first bonding pads is arranged in an array.

10. The semiconductor structure according to claim 9, wherein in the display region, the spacing between any two adjacent first bonding pads is 0.3 micron to 0.5 micron.

11. The semiconductor structure according to claim 2, wherein the first bonding pad comprises a bottom layer, an intermediate layer and a top layer, wherein the materials of the bottom layer and the top layer comprise titanium and titanium nitride, and the material of the intermediate layer comprises aluminum.

12. The semiconductor structure according to claim 1, wherein the ratio of an area of the display region to an area of the bonding pad region is greater than 20.

13. A method for forming a semiconductor structure including a light emitting element, comprising:
providing a substrate with a display region and a bonding pad region defined thereon;
forming a circuit layer on the substrate, and the circuit layer is located in the display region and the bonding pad region;
forming a plurality of contact plugs located in the display region and the bonding pad region and electrically connected with the circuit layer, wherein the contact plugs in the display region are arranged in an array; and
forming a plurality of light emitting elements, the plurality of light emitting elements are located in the display region and electrically connected with the contact plugs.

14. The method for forming a semiconductor structure including a light emitting element according to claim 13, further comprising forming a plurality of first bonding pads in the display region and between the light emitting element and the contact plug.

15. The method for forming a semiconductor structure including a light emitting element according to claim 14, wherein in the display region, each first bonding pad corresponds to each contact plug, and the first bonding pads are arranged in an array.

16. The method for forming a semiconductor structure including a light emitting element according to claim 14, wherein the first bonding pad directly contacts the contact plug and the light emitting element.

17. The method for forming a semiconductor structure including a light emitting element according to claim 14, further comprising forming a second bonding pad in the bonding pad region, and the second bonding pad is electrically connected to the contact plug.

18. The method for forming a semiconductor structure including a light emitting element according to claim 17, further comprising:
forming a metal layer;
performing a patterning step on the metal layer to remove part of the metal layer, wherein the remaining metal layer in the display region is defined as the first bonding pad, and the remaining metal layer in the bonding pad region is defined as the second bonding pad.

19. The method for forming a semiconductor structure including a light emitting element according to claim 17, further comprising forming a passivation layer covering the first bonding pad and the second bonding pad.

20. The method for forming a semiconductor structure including a light emitting element according to claim 19, further comprising performing a planarization step to the passivation layer, to flatten a top surface of the passivation layer.
